(19) United States
(12) Patent Application Publication
(10) Pub. No.: US 2024/0006461 A1
(43) Pub. Date: Jan. 4, 2024

(54) LIGHT EMITTING DEVICE AND IMAGE DISPLAY APPARATUS

(71) Applicant: SONY GROUP CORPORATION, Tokyo (JP)

(72) Inventors: Akira OHMAE, Tokyo (JP); Goshi BIWA, Tokyo (JP)

(73) Assignee: SONY GROUP CORPORATION, Tokyo (JP)

(21) Appl. No.: 18/254,234

(22) PCT Filed: Nov. 12, 2021
(86) PCT No.: PCT/JP2021/041706

§ 371 Date: May 24, 2023

(30) Foreign Application Priority Data
Dec. 4, 2020 (JP) 2020-202215

(51) Int. Cl. H01L 27/15; H01L 33/00; H01L 33/24; H01L 33/50; H01L 33/58; H01L 33/60

(52) U.S. Cl. CPC H01L 27/156; H01L 33/007; H01L 33/24; H01L 33/50; H01L 33/58; H01L 33/60; H01L 2933/0041; H01L 2933/0058

(57) ABSTRACT

A light-emitting device according to one embodiment of the present disclosure includes: a base having a first surface and a second surface that face each other; a structure having a first conductivity type and erected in a direction perpendicular to the first surface of the base; a semiconductor layer having a second conductivity type different from the first conductivity type, and provided on a side surface of the structure; and an active layer provided between the structure and the semiconductor layer, and having substantially same end surface as the structure and the semiconductor layer above the first surface of the base.

### TECHNICAL FIELD

The present disclosure relates to, for example, a light-emitting device having a plurality of light-emitting sections, and an image display apparatus including the same.

### BACKGROUND ART

For example, Patent Literature 1 discloses a light-emitting device having, as a light-emitting section, a plurality of columnar sections having diameters on the order of nm on a substrate, in which a first semiconductor layer, an active layer, and a second semiconductor layer are stacked in this order.

### CITATION LIST

### Patent Literature

Patent Literature 1: Japanese Unexamined Patent Application Publication No. 2019-054127

### SUMMARY OF THE INVENTION

Incidentally, for example, in a light-emitting device used as a light source or the like of a display pixel, an improvement in a light extraction efficiency is demanded.

It is desirable to provide a light-emitting device and an image display apparatus that make it possible to improve a light extraction efficiency.

A light-emitting device according to one embodiment of the present disclosure includes: a base having a first surface and a second surface that face each other; a structure having a first conductivity type and erected in a direction perpendicular to the first surface of the base; a semiconductor layer having a second conductivity type different from the first conductivity type, and provided on a side surface of the structure; and an active layer provided between the structure and the semiconductor layer, and having substantially same end surface as the structure and the semiconductor layer above the first surface of the base.

An image display apparatus according to one embodiment of the present disclosure includes a plurality of light-emitting devices, and has the light-emitting device according to one embodiment of the present disclosure as the light-emitting device.

In the light-emitting device of one embodiment of the present disclosure and the image display apparatus of one embodiment of the present disclosure, the active layer and the first semiconductor layer that is different from the first conductivity type are stacked in order on the side surface of the structure erected on the first surface of the base and having the first conductivity type, and the respective end surfaces provided above the first surface of the base have substantially the same surface. As a result, light emitted in the active layer is selectively extracted in a direction substantially perpendicular to the first surface of the base.

### BRIEF DESCRIPTION OF THE DRAWINGS

FIG. 1 is a cross-sectional schematic diagram illustrating an example of a configuration of a light-emitting device according to an embodiment of the present disclosure.

FIG. 2 is a perspective diagram describing a shape of the light-emitting device illustrated in FIG. 1.

FIG. 3 is a schematic cross-sectional diagram for describing a configuration example of the light-emitting device illustrated in FIG. 1 and an output direction of light.

FIG. 4A is a cross-sectional schematic diagram describing an example of a manufacturing process of the light-emitting device illustrated in FIG. 1.

FIG. 4B is a cross-sectional schematic diagram illustrating a process following FIG. 4A.

FIG. 4C is a cross-sectional schematic diagram illustrating a process following FIG. 4B.

FIG. 5A is a schematic cross-sectional diagram illustrating an example of a manufacturing process of an n-electrode and a p-electrode following FIG. 4C.

FIG. 5B is a schematic cross-sectional diagram illustrating another example of the manufacturing process of the n-electrode and the p-electrode following FIG. 4C.

FIG. 6A is a cross-sectional schematic diagram illustrating a process following FIG. 5A or FIG. 5B.

FIG. 6B is a cross-sectional schematic diagram illustrating a process following FIG. 6A.

FIG. 6C is a schematic cross-sectional diagram illustrating a process following FIG. 6B.

FIG. 6D is a cross-sectional schematic diagram illustrating a process following FIG. 6C.

FIG. 6E is a schematic cross-sectional diagram illustrating a process following FIG. 6D.

FIG. 7 is a perspective diagram illustrating an example of a configuration of an image display apparatus provided with the light-emitting device illustrated in FIG. 1.

FIG. 8 is a schematic diagram illustrating an example of a wiring line layout of the image display apparatus illustrated in FIG. 7.

FIG. 9 is a schematic cross-sectional diagram illustrating a configuration of a light-emitting device and an output direction of light in Comparative Example 1.

FIG. 10 is a schematic cross-sectional diagram illustrating a configuration of a light-emitting device and an output direction of light in Comparative Example 2.

FIG. 11 is a schematic diagram illustrating a cross-sectional configuration of a light-emitting device and a base (a semiconductor wafer) on which the light-emitting device is formed in Comparative Example 3.

FIG. 12 is a schematic diagram illustrating a cross-sectional configuration of the light-emitting device and a base (semiconductor wafer) on which the light-emitting device is formed according to the present embodiment.

FIG. 13A is a schematic cross-sectional diagram illustrating another example of a manufacturing process of the light-emitting device according to Modification Example 1 of the present disclosure.

FIG. 13B is a cross-sectional schematic diagram illustrating a process following FIG. 13A.

FIG. 13C is a schematic cross-sectional diagram illustrating a process following FIG. 13B.

FIG. 13D is a schematic cross-sectional diagram illustrating a process following FIG. 13C.

FIG. 13E is a schematic cross-sectional diagram illustrating a process following FIG. 13E.

FIG. 14 is a perspective diagram illustrating another example of a configuration of an image display apparatus according to Modification Example 2 of the present disclosure.

FIG. 15 is a perspective diagram illustrating a configuration of a mounting substrate illustrated in FIG. 14.

FIG. 16 is a perspective diagram illustrating a configuration of a unit substrate illustrated in FIG. 15.

### MODES FOR CARRYING OUT THE INVENTION

Hereinafter, embodiments of the present disclosure will be described in detail with reference to the drawings. The following description is a specific example of the present disclosure, and the present disclosure is not limited to the following embodiments. In addition, the present disclosure is not limited to the arrangement, dimensions, dimensional ratios, etc. of each component illustrated in each drawing. The order of description is as follows.
1. Embodiment (an example of a light-emitting device in which an active layer is provided on a side surface of a structure and light is extracted from the end surface)
   1-1. Configuration of light-Emitting Device
   1-2. Manufacturing Method of Light-Emitting Device
   1-3. Configuration of Image Display Apparatus
   1-4. Workings and Effects
2. Modification Examples
   2-1. Modification Example 1 (another example of a method for manufacturing the light-emitting device)
   2-2. Modification Example 2 (another example of the image display apparatus)

### 1. Embodiment

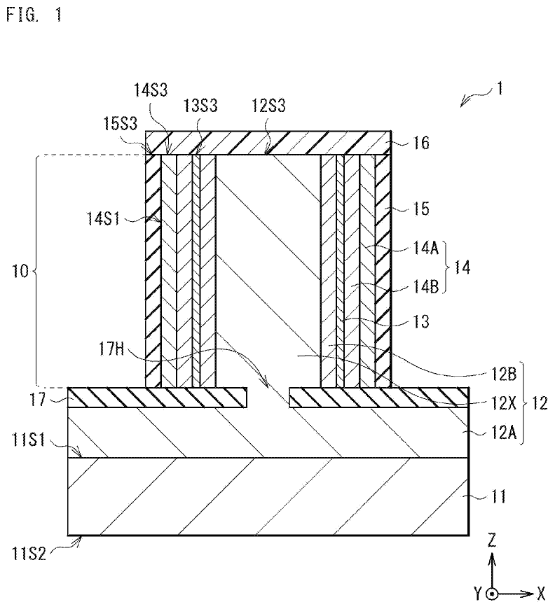

FIG. 1 schematically illustrates an example of a cross-sectional configuration of a light-emitting device (a light-emitting device 1) according to an embodiment of the present disclosure. FIG. 2 is a perspective diagram describing a shape of the light-emitting device 1 illustrated in FIG. 1. The light-emitting device 1 can be suitably applied to a display pixel of a display device referred to as a so-called LED display (for example, an image display apparatus 100, see FIG. 7).

The light-emitting device 1 of the present embodiment is a so-called nano-column type or nano-wire type light-emitting diode (LED), in which an active layer 13 and a p-type semiconductor layer 14 are provided on a side surface of a structure (a columnar structure 12X) including, for example, an n-type semiconductor and erected in a perpendicular direction (for example, a Z-axis direction) perpendicular to a first surface (a surface 11S1, such as an XY plane) of a base 11, and in which an end surface (a surface 13S3) of the active layer 13 and an end surface (a surface 14S3) of the p-type semiconductor layer 14 have substantially the same surface.

### 1-1. Configuration of Light-Emitting Device

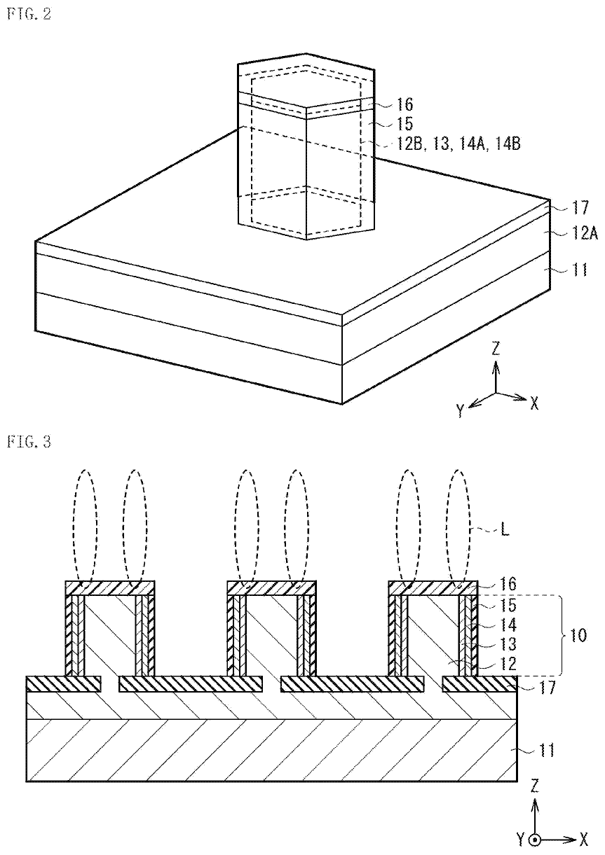

The light-emitting device 1 has one or a plurality of light-emitting sections 10 erected on the surface 11S1 of the base 11, as illustrated in FIG. 3, for example. Each light-emitting section 10 includes an n-type semiconductor layer 12 including the columnar structure 12X erected on the surface 11S1 of the base 11, and the active layer 13 and the p-type semiconductor layer 14 formed on the side surface of the columnar structure 12X in this order as described above. A light-shielding layer 15 is further formed on the side surface of the columnar structure 12X with the active layer 13 and the p-type semiconductor layer 14 interposed therebetween. An upper surface (a surface 12S3) of the columnar structure 12X, an end surface (the surface 13S3) of the active layer 13, an end surface (the surface 14S3) of the p-type semiconductor layer 14, and an end surface (a surface 15S43) of the light-shielding layer 15 form substantially the same surface as each other. A continuous light control layer 16 is provided on these surfaces 12S3, 13S3, 14S3, and 15S3. The n-type semiconductor layer 12 has, for example, an n-type contact layer 12A extending on the surface 11S1 of the base 11, and includes a light-reflecting layer 17 provided between the n-type contact layer 12A and the n-type semiconductor layer 12, the active layer 13, the p-type semiconductor layer 14, and the light-shielding layer 15 that form a columnar structure. The light-reflecting layer 17 has an opening 17H between the n-type contact layer 12A and the columnar structure 12X.

The base 11 is a plate-like member having a pair of opposing surfaces (the surface 11S1 and a surface 11S2), and is configured by a semiconductor wafer such as silicon (Si), gallium nitride (GaN), or sapphire. The surface 11S1 corresponds to a specific example of a “first surface” of the present disclosure, and the surface 11S2 corresponds to a specific example of a “second surface” of the present disclosure.

The n-type semiconductor layer 12 has the n-type contact layer 12A extending on the surface 11S1 of the base 11, and the columnar structure 12X and an n-type cladding layer 12B that structure the light-emitting section. As illustrated in FIG. 2, the columnar structure 12X is, for example, substantially hexagonal columnar-shaped and is erected in the Z-axis direction of the n-type contact layer 12A from the opening 17H of the light-reflecting layer 17, and has a shape in which the area of the side surface (a growth surface in the XY plane direction) is larger than the area of the top surface. The n-type cladding layer 12B is provided on the side surface of the columnar structure 12X. The n-type semiconductor layer 12 includes, for example, an n-type GaN-based semiconductor material. The n-type semiconductor layer 12 including the columnar structure 12X corresponds to a specific example of a “structure” of the present disclosure.

The active layer 13 is provided, for example, on a side surface of the n-type semiconductor layer 12 erected in the Z-axis direction (specifically, on the n-type cladding layer 12B). The active layer 13 has, for example, a multiple quantum well structure in which InGaN and GaN are alternately stacked. The active layer 13 emits light in a blue region with an emission wavelength of 430 nm or more and 500 nm or less, for example. Alternatively, the active layer 13 may emit light in an ultraviolet region with an emission wavelength of 350 nm or more and 430 nm or less. Alternatively, the active layer 13 may emit light in a green or red wavelength band, or emit multiple wavelengths on the same base.

The p-type semiconductor layer 14 has a p-type cladding layer 14B and a p-type contact layer 14A. The p-type cladding layer 14B and the p-type contact layer 14A are provided in this order on the active layer 13 along the side surface of the columnar structure 12X. The p-type semiconductor layer 14 includes, for example, a p-type GaN-based semiconductor material.

The light-shielding layer 15 confines light L emitted in the active layer 13 inside the light-emitting section 10, and guides the light above the light-emitting section 10 (in the Z-axis direction, specifically, a surface opposite to the base 11 side (a light emission layer 15)), and is provided on the p-type semiconductor layer 14 along the side surface of the columnar structure 12X. The light-shielding layer 15 is preferably formed using a material that has a light shielding property and further has a light reflectivity. Examples of such a material include aluminum (Al), silver (Ag), and rhodium (Rh). The light-shielding layer 15 can be omitted in a case where the n-type cladding layer 12B and the p-type cladding layer 14B have a light confinement effect.

The upper surface (the surface 12S3) of the n-type semiconductor layer 12 including the columnar structure 12X, the end surface (the surface 13 S3) of the active layer 13, and the end surface (the surface 14S3) of the p-type semiconductor layer 14 have substantially the same surface as each other as described above, and form a light output surface of the light-emitting section 10.

The light control layer 16 is for providing a refractive index difference between the light output surfaces (the surfaces 12S3, 13S3, 14S3) of the light-emitting section 10. For example, the light control layer 16 is continuously provided on the surfaces 12S3, 13 S3, and 14S3 and the end surface (the surface 15S3) of the light-shielding layer 15. The light control layer 16 is formed using a dielectric material, for example. Examples of the dielectric material include oxide, nitride, fluoride, or the like of silicon (Si), magnesium (Mg), Al, Hf, niobium (Nb), zirconium (Zr), scandium (Sc), tantalum (Ta), gallium (Ga), zinc (Zn), yttrium (Y), boron (B), or titanium (Ti). In addition, a fine structure such as a metasurface using the above material can also be used.

The light-reflecting layer 17 is for guiding the light L outputted from the active layer 13 toward the base 11 side and reflected by the light-shielding layer 15 to the upper side of the light-emitting section 10, that is, the light output surface. The light-reflecting layer 17 is provided between the n-type contact layer 12A extending to the surface 11S1 of the base 11 and the light-emitting section 10. As described above, the light-reflecting layer 17 has the opening 17H between the n-type contact layer 12A and the columnar structure 12X. The light-reflecting layer 17 is configured by a metal film having light reflectivity or a distributed Bragg reflector (DBR). Materials of the metal film include, for example, Al, Ag, and Rh. The DBR is a multilayer film in which dielectric films having different refractive indices from each other are alternately stacked. Examples of the dielectric materials include oxide, nitride, fluoride, or the like of silicon (Si), magnesium (Mg), Al, Hf, niobium (Nb), zirconium (Zr), scandium (Sc), tantalum (Ta), gallium (Ga), zinc (Zn), yttrium (Y), boron (B), and titanium (Ti). The light-reflecting layer 17 can be formed as a single layer of the metal film or the DBR, or as a stacked film of the metal film and the DBR. In a case of the stacked film, it is preferable to provide the metal film on a lower layer (on the base 11 side) and the DBR on an upper layer (on the light-emitting section 10 side).

In this way, the light-shielding layer 15 is formed in a side surface direction of the columnar structure 12X erected in the direction perpendicular to the surface 11S1 of the base 11, that is, the side surface of the light-emitting section 10, the light control layer 16 is provided on the light output surface configured by the surfaces 1253, 1353, and 1453 of the n-type semiconductor layer 12, the active layer 13, and the p-type semiconductor, and the light-reflecting layer 17 is provided between the base 11 (specifically, the n-type contact layer 12A) and the light-emitting section 10. As a result, as illustrated in FIG. 3, the light L emitted from the active layer 13 can be confined within the light-emitting section 10 and selectively extracted from above the light-emitting section 10.

### 1-2. Manufacturing Method of Light-Emitting Device

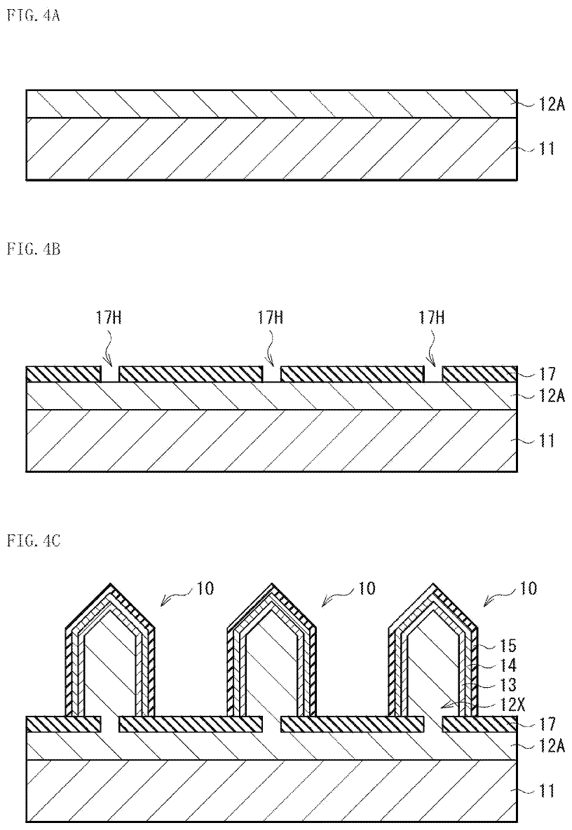

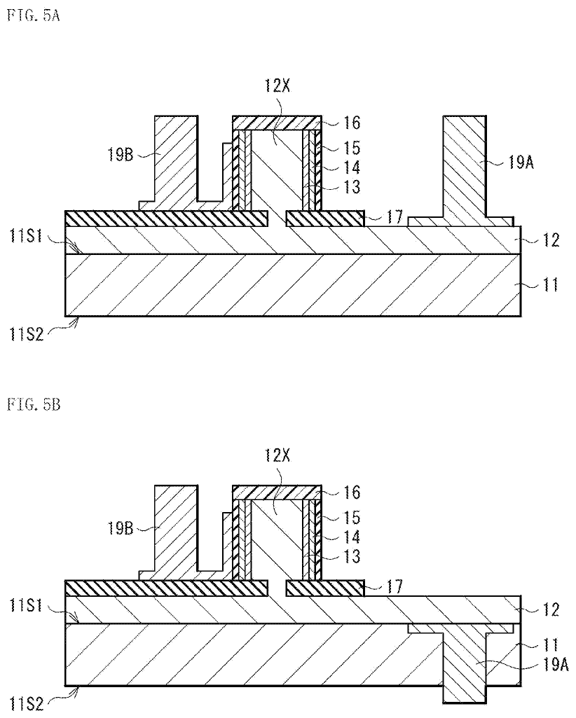

The light-emitting device 1 can be manufactured, for example, as follows. FIGS. 4A to 4C, 5A, 5B, and 6A to 6E illustrate an example of a method of manufacturing the light-emitting device 1.

First, as illustrated in FIG. 4A, the n-type contact layer 12A is formed on the base 11 by, for example, an epitaxial crystal growth using a method such as a metal organic chemical vapor deposition (MOCVD: Metal Organic Chemical Vapor Deposition) method or a molecular beam epitaxy (MBE: Molecular Beam Epitaxy) method. Subsequently, as illustrated in FIG. 4B, the light-reflecting layer 17 having the opening 17H at a predetermined position is formed on the n-type contact layer 12A by using, for example, a chemical vapor deposition method (CVD method).

Next, as illustrated in FIG. 4C, using the light-reflecting layer 17 as a mask, the columnar structure 12X, the n-type cladding layer 12B, the active layer 13, and the p-type semiconductor layer 14 (the p-type cladding layer 14B and the p-type contact layer 14A) are grown in order on the n-type contact layer 12A exposed on the opening 17H by an epitaxial growth to form the plurality of light-emitting sections 10. Subsequently, for example, the light-shielding layer 15 is formed on the surface of the light-emitting section 10 using the CVD method.

Next, as illustrated in FIG. 5A, a portion of the light-reflecting layer 17 is removed to form an n-electrode 19A electrically coupled to the n-type contact layer 12A. Further, a p-electrode 19B extending from an upper part of the light-reflecting layer 17 to the light-shielding layer 15 is formed by atomic layer deposition (an ALD method), for example. The n-electrode 19A may be taken out from the surface 11S2 side of the base 11 as illustrated in FIG. 5B. In that case, the n-electrode 19A may be formed, for example, after the light control layer 16 is formed.

The n-electrode 19A and the p-electrode 19B can be formed using a transparent electrode material such as Indiun Tin Oxide (ITO) or Indiun Zinc Oxide (IZO). In addition, the n-electrode 19A and the p-electrode 19B may be formed using a metal material such as palladium (Pd), titanium (Ti), aluminum (Al), platinum (Pt), silver (Ag), nickel (Ni) or gold (Au). The n-electrode 19A is provided, for example, as a common electrode for the plurality of light-emitting sections 10. The p-electrode 19B may be provided individually for each light-emitting section or may be provided as a common electrode for the plurality of light-emitting sections 10, similar to the n-electrode 19A. Further, the p-electrode 19B can be used as the light-shielding layer 15 by using a metal material having light reflectivity such as Al described above as the material of the p-electrode 19B.

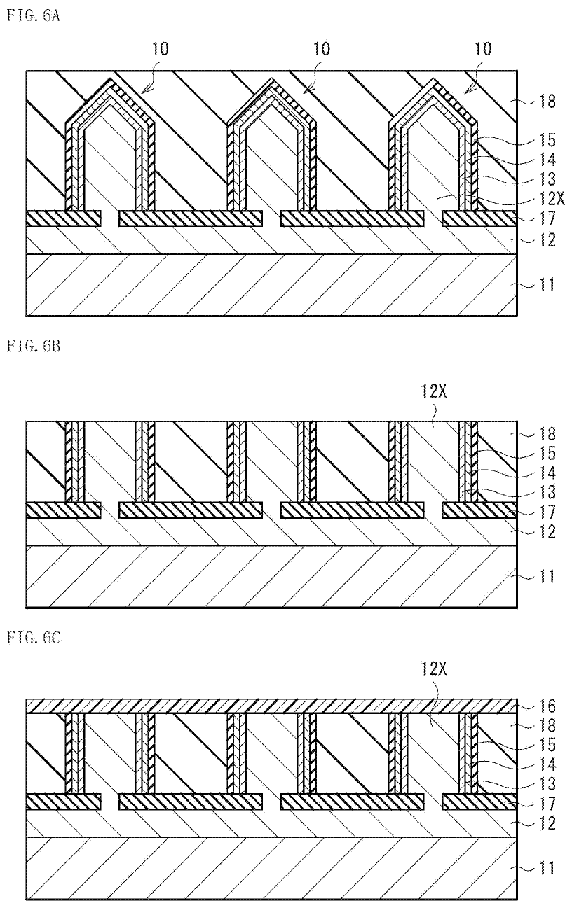

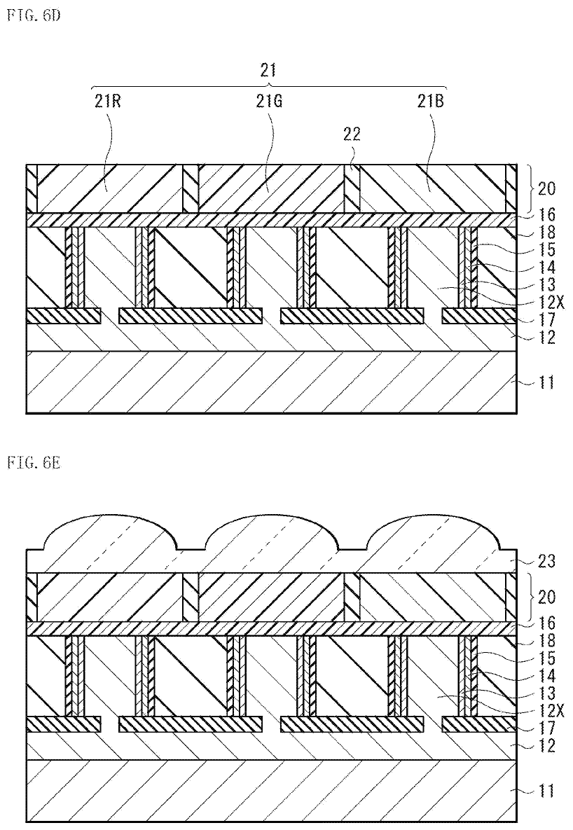

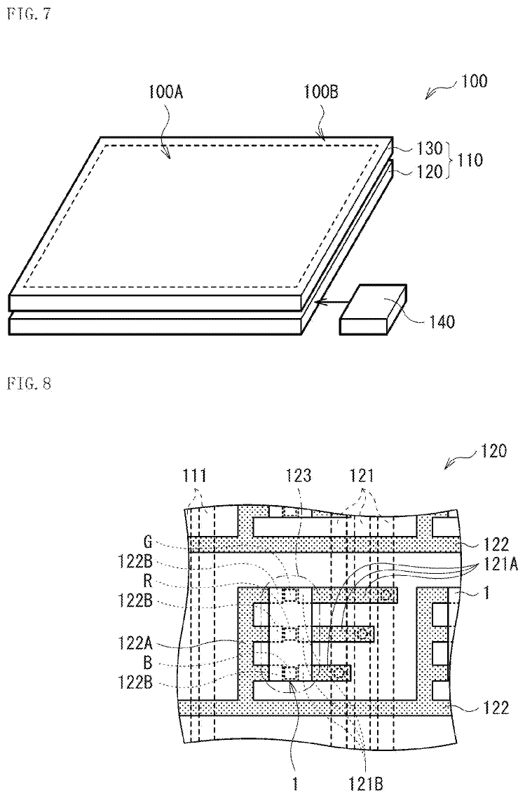

Next, as illustrated in FIG. 6A, for example, the CVD method is used to form an insulating film 18 that includes, for example, SiOx to embed the plurality of light-emitting sections Subsequently, as illustrated in FIG. 6B, for example, the upper portions of the insulating film 18 and the plurality of light-emitting sections 10 are ground using a CMP (Chemical Mechanical Polishing) method, and the columnar structure 12X, the n-type cladding layer 12B, the active layer 13, the p-type cladding layer 14B, the p-type contact layer 14A, the light-shielding layer 15, and the insulating film 18 are flattened such that their respective end faces have substantially the same surface.

It should be noted that the columnar structure 12X, the n-type cladding layer 12B, the active layer 13, the p-type cladding layer 14B, the p-type contact layer 14A, the light-shielding layer 15, and the insulating film 18 may be flattened by dry etching, for example.

Next, as illustrated in FIG. 6C, the light control layer 16 is formed using, for example, the CVD method on the flat surface configured by the columnar structure 12X, the n-type cladding layer 12B, the active layer 13, the p-type cladding layer 14B, the p-type contact layer 14A, the light-shielding layer 15, and the insulating film 18. Subsequently, as illustrated in FIG. 6D, a wavelength conversion section 20 having a color conversion layer 21 (21R, 21G, and 21B) and a separation section 22 is formed on the light control layer 16.

The color conversion layer 21 is for converting the light L outputted from the plurality of columnar structures 12X into desired wavelengths (for example, red (R)/green (G)/blue (B)) and outputting the light. Each of the color conversion layers 21R, 21G, and 21B can be formed using quantum dots corresponding to each color. Specifically, in a case of obtaining red light, the quantum dots can be selected from, for example, InP, GaInP, InAsP, CdSe, CdZnSe, CdTeSe, CdTe, or the like. In a case of obtaining green light, the quantum dots can be selected from, for example, InP, GaInP, ZnSeTe, ZnTe, CdSe, CdZnSe, CdS, CdSeS, or the like. In a case of obtaining blue light, the quantum dots can be selected from ZnSe, ZnTe, ZnSeTe, CdSe, CdZnSe, CdS, CdZnS, CdSeS, or the like. In a case where the active layer 13 emits the light in the blue region (blue light) as described above, the color conversion layer 21B may be formed by a resin layer having light transparency.

The separation section 22 is for suppressing an occurrence of a color mixture due to a leakage of light between the adjacent color conversion layers 21R, 21G, and 21B. The separation section 22 can be formed using a light-shielding material such as tungsten (W), for example.

Thereafter, as illustrated in FIG. 6E, a lens array 23 is attached on the wavelength conversion section 20. As described above, the light-emitting device 1 having the light-emitting sections 10R, 10G, and 10B, which is used for, for example, the display pixels 123 of the image display apparatus 100 (FIG. 7) described later, is completed.

### 1-3. Configuration of Image Display Apparatus

FIG. 7 is a perspective diagram illustrating an example of a schematic configuration of an image display apparatus (the image display apparatus 100). The image display apparatus 100 is a so-called LED display, and uses the light-emitting device 1 of the present embodiment as the display pixel 123. The image display apparatus 100 includes, for example, a display panel 110 and a control circuit 140 that drives the display panel 110, as illustrated in FIG. 7.

The display panel 110 is obtained by overlaying a mounting substrate 120 and a counter substrate 130 on each other. A surface of the counter substrate 130 serves as an image display surface, and has a display region 100A at a middle part, and a frame region 100B as a non-display region therearound.

FIG. 8 illustrates an example of a wiring line layout of a region corresponding to the display region 100A on a surface of the mounting substrate 120 on the counter substrate 130 side. In the region corresponding to the display region 100A on the surface of the mounting substrate 120, for example, as illustrated in FIG. 8, a plurality of data wiring lines 121 are formed extending in a predetermined direction and disposed side by side at a predetermined pitch. In the region corresponding to the display region 100A on the surface of the mounting substrate 120, for example, a plurality of scan wiring lines 122 are further formed extending in a direction intersecting (for example, perpendicular to) the data wiring lines 121 and are disposed side by side at a predetermined pitch. The data wiring line 121 and the scan wiring line 122 include an electrically conductive material such as Cu (copper), for example.

The scan wiring line 122 is formed, for example, on an outermost layer, for example, on an insulating layer (not illustrated) formed on a base surface. A base of the mounting substrate 120 includes, for example, a silicon substrate or a resin substrate, and the insulating layer on the base includes, for example, silicon nitride (SiN), silicon oxide (SiO), aluminum oxide (AlO) or a resin material. On the other hand, the data wiring line 121 is formed in a layer (for example, a layer below the outermost layer) different from the outermost layer including the scan wiring line 122, and is, for example, formed in the insulating layer on the base.

The display pixel 123 is formed in the vicinity of an intersection of the data wiring line 121 and the scan wiring line 122, and the plurality of display pixels 123 are disposed in a matrix in the display region 100A. Each display pixel 123 is mounted with the light-emitting device 1 having, for example, three light-emitting sections 10 (hereinafter referred to as light-emitting sections 10R, 10G, and 10B) corresponding to RGB. FIG. 8 illustrates an example in which one display pixel 123 is configured by three light-emitting sections 10R, 10G, and 10B, and in which red light is configured to be outputted from the light-emitting section 10R, green light is configured to be outputted from the light-emitting section 10G, and blue light is configured to be outputted from the light-emitting section 10B.

The light-emitting device 1 is provided with, for example, a pair of terminal electrodes for each of the light-emitting sections 10R, 10G, and 10B, or one of which is common and the other of which is disposed for each of the light-emitting sections 10R, 10G, and 10B. One terminal electrode is electrically coupled to the data wiring line 121 and the other terminal electrode is electrically coupled to the scan wiring line 122. For example, one terminal electrode is electrically coupled to a pad electrode 121B at a tip of a branch 121A provided on the data wiring line 121. In addition, for example, the other terminal electrode is electrically coupled to a pad electrode 122B at a tip of a branch 122A provided on the scan wiring line 122.

Each pad electrode 121B, 122B is formed, for example, on the outermost layer, and is provided at a location where each light-emitting device 1 is mounted, for example, as illustrated in FIG. 8. Here, the pad electrodes 121B and 122B include an electrically conductive material such as Au (gold).

The mounting substrate 120 is further provided with, for example, a plurality of pillars (not illustrated) that regulate a spacing between the mounting substrate 120 and the counter substrate 130. The pillars may be provided in a region facing the display region 100A, or may be provided in a region facing the frame region 100B.

The counter substrate 130 includes, for example, a glass substrate or a resin substrate. In the counter substrate 130, a surface on the light-emitting device 1 side may be flat, but is preferably rough. The rough surface may be provided over the entire region facing the display region 100A, or may be provided only in the region facing the display pixel 123. The rough surface has fine unevenness on which the light emitted from the light-emitting sections 10R, 10G, and 10B enters. The unevenness of the rough surface can be produced by, for example, sandblasting, dry etching, or the like.

The control circuit 140 drives each display pixel 123 (each light-emitting device 1) on the basis of a picture signal. The control circuit 140 includes, for example, a data driver that drives the data wiring lines 121 coupled to the display pixels 123 and a scan driver that drives the scan wiring lines 122 coupled to the display pixels 123. For example, as illustrated in FIG. 7, the control circuit 140 may be provided separately from the display panel 110 and coupled to the mounting substrate 120 via a wiring line, or may be mounted on the mounting substrate 120.

### 1-4. Workings and Effects

In the light-emitting device 1 of the present embodiment, the n-type cladding layer 12B, the active layer 13, and the p-type semiconductor layer 14 (the p-type contact layer 14A and the p-type cladding layer 14B) are stacked in this order on the side surface of the columnar structure 12X erected in the perpendicular direction (the Z-axis direction) perpendicular to the surface 11S1 of the base 11, and the respective end surfaces (the surfaces 12S3, 13S3, and 14S3) provided above the base 11 have substantially the same surface. As a result, the light L emitted in the active layer 13 is selectively extracted from the light output surface configured by the surfaces 12S3, 13S3, and 14S3 having substantially the same surface. This will be explained below.

High definition is desired for an LED display that uses light emitting diodes (LEDs) as light sources. In order to achieve the high definition, a method of increasing an integration density of RGB in one pixel is conceivable.

However, if an attempt is made to increase the integration density of RGB by using generals LED in which crystals of semiconductor laminates are grown in a direction perpendicular to a substrate, it becomes difficult to create pixels. For example, in order to form an RGB separation and a shielding structure between pixels and within a pixel, and a structure for introducing excitation light to a color conversion layer provided above the LEDs, it is necessary to use multiple structurally difficult techniques.

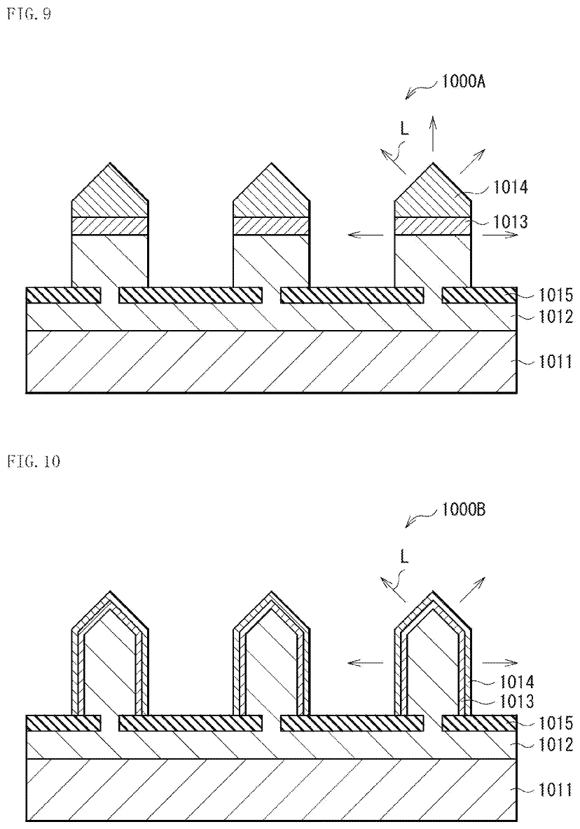

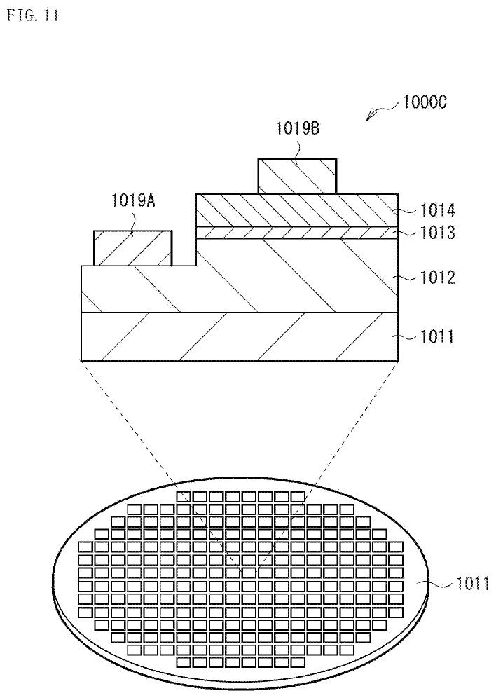

On the other hand, as a light-emitting device with a high integration density and in which a separation between devices is easy, a light-emitting device 1000A (FIG. 9) has been developed in which a columnar section having a diameter on the order of nanometers and in which a first semiconductor layer, an active layer, and a second semiconductor layer are stacked in this order is provided as a light-emitting section as described above. In addition, a light-emitting device 1000B having an active layer on a side surface of the columnar section is also contemplated (FIG. 10).

However, in the light-emitting device 1000A or 1000B, light L emitted in the active layer is outputted in all directions of the columnar section as illustrated in FIGS. 9 and 10. For this reason, it is important to shield RGB between pixels and within pixels, and an improvement in an efficiency of extracting light upward from the columnar section is a problem.

In contrast, in the present embodiment, the active layer 13 and the p-type semiconductor layer 14 are stacked on the side surface of the n-type semiconductor layer 12 forming the columnar structure 12X erected in the direction perpendicular to the surface 11S1 of the base 11, and the respective end surfaces (the surfaces 12S3, 13S3, and 14S3) have substantially the same end surface. As a result, the light L emitted in the active layer 13 can be selectively extracted in the perpendicular direction of the base 11, i.e., above the light-emitting section 10, as illustrated in FIG. 3.

As described above, in the light-emitting device 1 of the present embodiment, it is possible to improve the efficiency of extracting light upward of the light-emitting section 10 erected on the base 11.

Further, in the present embodiment, the light-shielding layer 15 is provided on the side surface of the columnar structure 12X (specifically, the surface 14S1 of the p-type semiconductor layer 14). Further, in the present embodiment, between the base 11 and the light-emitting section (specifically, between the n-type contact layer 12A and a portion of the columnar structure 12X, the n-type cladding layer 12B, the active layer 13, and the p-type semiconductor layer 14), the light-reflecting layer 17 is further provided. Furthermore, the light control layer 16 is provided on the light output surface configured by the surfaces 12S3, 13 S3 and 14S3. As a result, the light L emitted in the active layer 13 can be more selectively extracted above the light-emitting section and the light extraction efficiency of the light-emitting device 1 can be further improved.

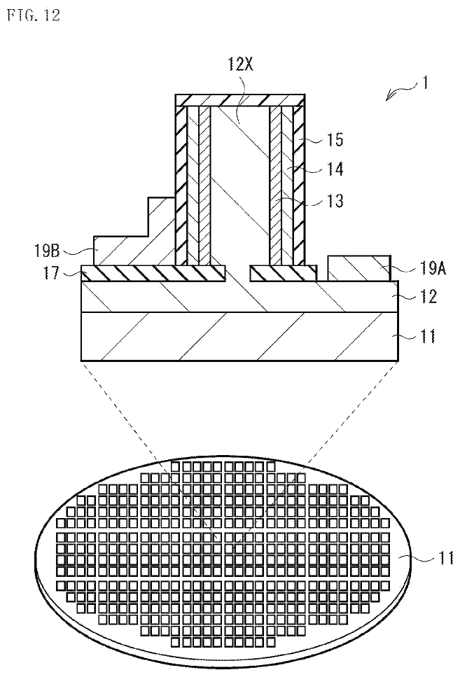

Furthermore, in the light-emitting device 1 of the present embodiment, because a structure is employed in which the active layer 13 is provided on the side surface of the columnar structure 12X erected on the surface 11S1 of the base 11, it is possible to improve high integration and production efficiency as illustrated in FIG. 12 as compared with a general light-emitting device 1000C in which an n-type semiconductor layer 1012, an active layer 1013, and a p-type semiconductor layer 1014 are stacked in this order on a base 1011 (a semiconductor wafer), as illustrated in FIG. 11.

Next, modification examples (modification examples 1 and 2) of the present disclosure will be described. In the following, the same reference numerals are assigned to the similar constituent elements to the above-described embodiment, and the description thereof will be omitted as appropriate.

### 2. Modification Examples

### 2-1. Modification Example 1

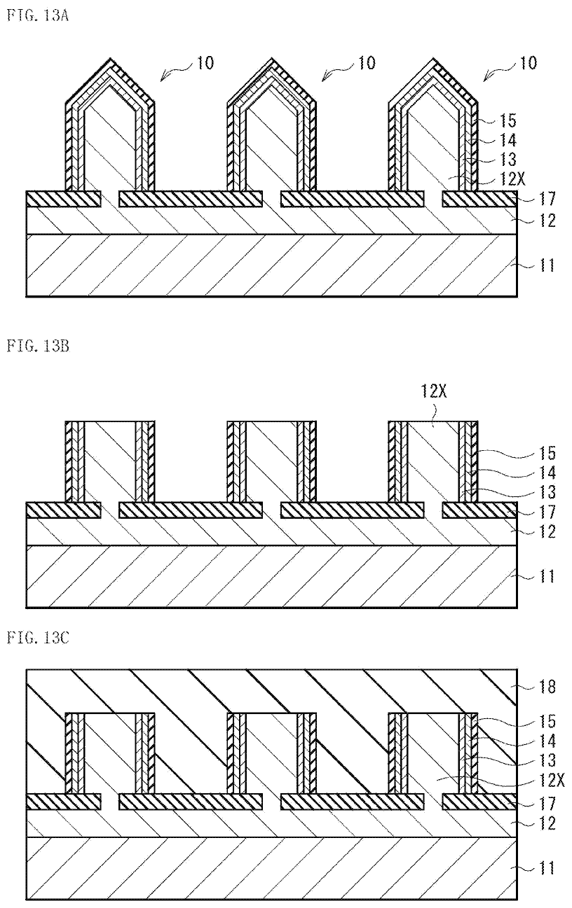

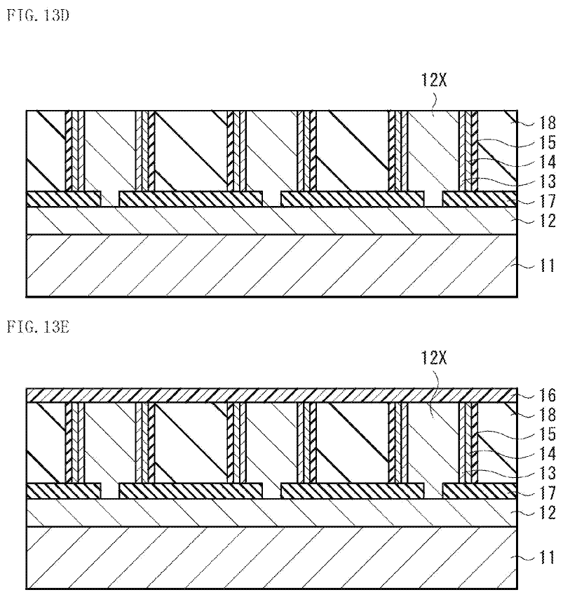

The light-emitting device 1 described in the above embodiment can be manufactured, for example, in the following manner, besides the manufacturing processes described above. FIGS. 13A to 13E illustrate another example of the method of manufacturing the light-emitting device 1.

First, as in the above embodiment, using the light-reflecting layer 17 provided on the n-type contact layer 12A as a mask, the columnar structure 12X, the n-type cladding layer 12B, the active layer 13, and the p-type semiconductor layer 14 (the p-type cladding layer 14B and p-type contact layer 14A) are epitaxially grown in order to form the plurality of light-emitting sections 10. Subsequently, the light-shielding layer 15 is formed on the surface of the light-emitting section 10 by using the CVD method, for example.

Next, as illustrated in FIG. 13B, for example, the CMP method is used to grind the upper part of the light-emitting section 10, and the columnar structure 12X, the n-type cladding layer 12B, the active layer 13, the p-type cladding layer 14B, the p-type contact layer 14A, and the light-shielding layer 15 are flattened such that the respective end surfaces thereof have substantially the same surface. Subsequently, the n-electrode 19A and the p-electrode 19B are formed (not illustrated) in the similar manner to the above embodiment.

Next, as illustrated in FIG. 13C, for example, the CVD method is used to form the insulating film 18 that includes, for example, SiOx to bury the light-emitting section 10. Subsequently, as illustrated in FIG. 13D, the insulating film 18 is ground using, for example, the CMP method to expose the light-emitting section 10 and flatten the same.

Next, as illustrated in FIG. 13E, the light control layer 16 is formed using, for example, the CVD method on the flat surface configured by the columnar structure 12X, the n-type cladding layer 12B, the active layer 13, the p-type cladding layer 14B, the p-type contact layer 14A, the light-shielding layer 15, and the insulating film 18. Thereafter, in a similar manner to the above embodiment, the wavelength conversion section 20 having the color conversion layer 21 (21R, 21G, and 21B) and the separation section 22 and the lens array 23 are formed in this order on the light control layer 16.

It should be noted that, although an example is illustrated in which the insulating film 18 fills a space between the plurality of light-emitting sections 10 in the above-described embodiment and the present modification example, the insulating film 18 may be removed as necessary.

### 2-2. Modification Example 2

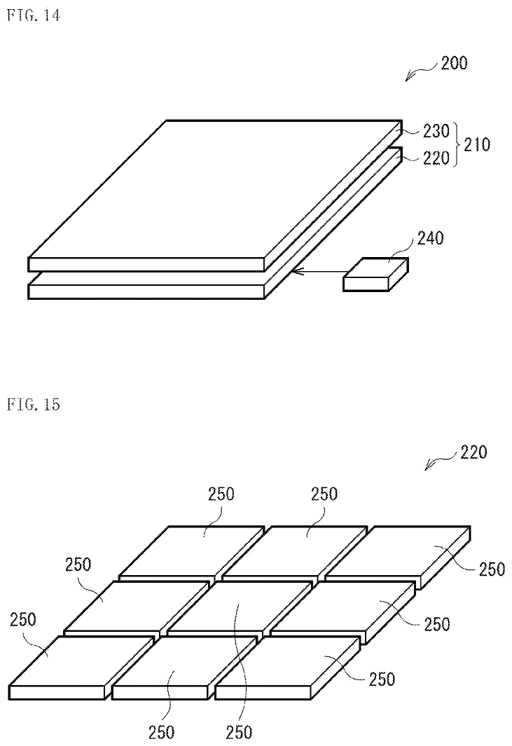

FIG. 14 is a perspective diagram illustrating another configuration example (an image display apparatus 200) of the image display apparatus using the light-emitting device (for example, the light-emitting device 1) of the present disclosure. The image display apparatus 200 is a so-called tiling display that uses LEDs as light sources, and uses the light-emitting device 1 of the present embodiment as the display pixel. For example, as illustrated in FIG. 14, a display panel 210 and a control circuit 240 that drives the display panel 210 are provided.

The display panel 210 is obtained by superimposing a mounting substrate 220 and a counter substrate 230 on each other. A surface of the counter substrate 230 serves as a picture display surface, and has a display region in a middle portion and a frame region as a non-display region therearound (both not illustrated). The counter substrate 230 is disposed, for example, at a position facing the mounting substrate 220 with a predetermined gap therebetween. It should be noted that the counter substrate 230 may be in contact with a top surface of the mounting substrate 220.

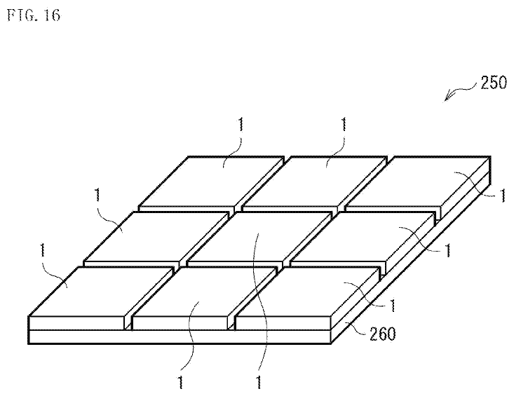

FIG. 15 schematically illustrates an example of a configuration of the mounting substrate 220. For example, as illustrated in FIG. 15, the mounting substrate 220 is configured by a plurality of unit substrates 250 laid out like tiles. Although FIG. 15 illustrates an example in which the mounting substrate 220 is configured by nine unit substrates 250, the number of unit substrates 250 may be ten or more, or may be eight or less.

FIG. 16 illustrates an example of a configuration of the unit substrate 250. The unit substrate 250 includes, for example, the light-emitting device 1 having a plurality of light-emitting sections (for example, the light-emitting sections 10R, 10G, and 10B) laid out like tiles, and a support substrate 260 supporting each light-emitting device 1. Each unit substrate 250 further has a control substrate (not illustrated). The support substrate 260 is configured by, for example, a metal frame (a metal plate) or a wiring substrate or the like. In a case where the support substrate 260 is configured by a wiring board, it can also serve as the control substrate. At this time, at least one of the support substrate 260 or the control substrate is electrically coupled to each light-emitting device 1.

Although the present disclosure has been described above with reference to the embodiment and modification examples 1 and 2, the present disclosure is not limited to the above-described embodiment, and various modifications are possible. For example, the components, arrangement, number, and the like of the light-emitting device (the light-emitting device 1) exemplified in the above embodiments and the like are merely examples, and it is not necessary to include all components, and other components may be further provided.

In addition, in the above embodiments and the like, the columnar n-type semiconductor layer 12 is described as a specific example of the structure, but the structure is not limited thereto. For example, the structure may be a sheet-like structure having a side surface extending in one direction (e.g., a Y-axis direction) with respect to an XY plane of the base 11 and in which the area of the side surface is larger than the area of a top surface.

Furthermore, in the above-described embodiments and the like, examples are illustrated in which the light-emitting device 1 is applied to the image display apparatuses 100 and 200, etc., but the light-emitting device (the light-emitting device 1) of the present disclosure can also be used, for example, as a light source of a ranging device or a light-emitting section of a communication system that communicates by a light signal.

Note that the effects described in this specification are merely examples and are not limited thereto, and other effects may be provided.

The present technology can also be configured as follows. According to the present technology having the following configuration, an active layer and a semiconductor layer different from a first conductivity type are stacked in order on a side surface of a structure having the first conductivity type and erected on a first surface of a base, and respective end surfaces provided above the first surface of the base have substantially the same surface. As a result, light emitted in the active layer can be selectively extracted in a direction substantially perpendicular to the first surface of the base. Therefore, it becomes possible to improve a light extraction efficiency.

(1)

A light-emitting device including:
a base having a first surface and a second surface that face each other;
a structure having a first conductivity type and erected in a direction perpendicular to the first surface of the base;
a semiconductor layer having a second conductivity type different from the first conductivity type, and provided on a side surface of the structure; and
an active layer provided between the structure and the semiconductor layer, and having substantially same end surface as the structure and the semiconductor layer above the first surface of the base.
   (2)

The light-emitting device according to (1), further including a light control layer continuous with the end surfaces of the structure, the active layer, and the semiconductor layer.

(3)

The light-emitting device according to (2), in which the light control layer includes a dielectric material.

(4)

The light-emitting device according to any one of (1) to (3), further including a reflective layer provided on the first surface of the base, having light reflectivity, and having an opening below the structure.

(5)

The light-emitting device according to (4), in which the reflective layer includes a distributed Bragg reflector.

(6)

The light-emitting device according to (4), in which the reflective layer includes a metal film.

(7)

The light-emitting device according to any one of (1) to (6), further including a light-shielding layer having light reflectivity and provided on a side of the semiconductor layer opposite to the active layer side.

(8)

The light-emitting device according to any one of (1) to (7), further including:
a first electrode electrically coupled to the structure and taken out from the second surface side of the base; and
a second electrode provided on the first surface side of the base and electrically coupled to the semiconductor layer.
   (9)

The light-emitting device according to any one of (1) to (7), further including:
a first electrode electrically coupled to the structure and taken out from the first surface side of the base; and
a second electrode provided on the first surface side of the base and electrically coupled to the semiconductor layer.
   (10)

The light-emitting device according to any one of (1) to (9), further including a wavelength conversion section that is provided above the end surfaces of the structure, the active layer, and the semiconductor layer, and converts a wavelength of light to be outputted from the active layer.

(11)

The light-emitting device according to any one of (1) to (10), further including a lens provided above the end surfaces of the structure, the active layer, and the semiconductor layer.

(12)

The light-emitting device according to any one of (1) to (11), in which the structure has a columnar shape.

(13)

An image display apparatus including
one or a plurality of light-emitting devices,
the light-emitting device including:
   a base having a first surface and a second surface that face each other;
   a structure having a first conductivity type and erected in a direction perpendicular to the first surface of the base;
   a semiconductor layer having a second conductivity type different from the first conductivity type, and provided on a side surface of the structure; and
   an active layer provided between the structure and the semiconductor layer, and having substantially same end surface as the structure and the semiconductor layer above the first surface of the base.

The present application claims the benefit of Japanese Priority Patent Application JP2020-202215 filed with the Japan Patent Office on Dec. 4, 2020, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A light-emitting device comprising:
a base having a first surface and a second surface that face each other;
a structure having a first conductivity type and erected in a direction perpendicular to the first surface of the base;
a semiconductor layer having a second conductivity type different from the first conductivity type, and provided on a side surface of the structure; and
an active layer provided between the structure and the semiconductor layer, and having substantially same end surface as the structure and the semiconductor layer above the first surface of the base.

2. The light-emitting device according to claim 1, further comprising a light control layer continuous with the end surfaces of the structure, the active layer, and the semiconductor layer.

3. The light-emitting device according to claim 2, wherein the light control layer includes a dielectric material.

4. The light-emitting device according to claim 1, further comprising a reflective layer provided on the first surface of the base, having light reflectivity, and having an opening below the structure.

5. The light-emitting device according to claim 4, wherein the reflective layer comprises a distributed Bragg reflector.

6. The light-emitting device according to claim 4, wherein the reflective layer comprises a metal film.

7. The light-emitting device according to claim 1, further comprising a light-shielding layer having light reflectivity and provided on a side of the semiconductor layer opposite to the active layer side.

8. The light-emitting device according to claim 1, further comprising:
a first electrode electrically coupled to the structure and taken out from the second surface side of the base; and
a second electrode provided on the first surface side of the base and electrically coupled to the semiconductor layer.

9. The light-emitting device according to claim 1, further comprising:
a first electrode electrically coupled to the structure and taken out from the first surface side of the base; and
a second electrode provided on the first surface side of the base and electrically coupled to the semiconductor layer.

10. The light-emitting device according to claim 1, further comprising a wavelength conversion section that is provided above the end surfaces of the structure, the active layer, and the semiconductor layer, and converts a wavelength of light to be outputted from the active layer.

11. The light-emitting device according to claim 1, further comprising a lens provided above the end surfaces of the structure, the active layer, and the semiconductor layer.

12. The light-emitting device according to claim 1, wherein the structure has a columnar shape.

13. An image display apparatus, comprising
one or a plurality of light-emitting devices,
the light-emitting device including:
a base having a first surface and a second surface that face each other;
a structure having a first conductivity type and erected in a direction perpendicular to the first surface of the base;
a semiconductor layer having a second conductivity type different from the first conductivity type, and provided on a side surface of the structure; and
an active layer provided between the structure and the semiconductor layer, and having substantially same end surface as the structure and the semiconductor layer above the first surface of the base.
